(19) United States
(12) Patent Application Publication
(10) Pub. No.: US 2006/0120050 A1
(43) Pub. Date: Jun. 8, 2006

(54) Closed loop heat dissipation apparatus

(76) Inventors: Win-Haw Chen, Taipei (TW); Mao-Ching Lin, Taipei (TW); Shu-Ju Lin, Taipei (TW)

Correspondence Address: HARNESS, DICKEY & PIERCE, P.L.C., P.O. BOX 8910, RESTON, VA, 20195, US

(21) Appl. No.: 11/003,379

(22) Filed: Dec. 6, 2004

(51) Int. Cl. H05K 7/20

(52) U.S. Cl. 361/700

(57) ABSTRACT

A closed loop heat dissipation apparatus includes a heat transfer seat containing an operation fluid, a seal lid attaching to a heat generating element and sealing one side of the heat transfer seat to hold the operation fluid therein, a tube made of flexible metal to couple on the heat transfer seat in a bendable manner and a radiation fin assembly mounted on the tube. The operation fluid absorbs the heat energy of the heat generating element and circulates in the tube to evenly distribute the heat energy, and is condensed to liquid phase to flow back to the heat transfer seat. The apparatus may be fabricated at a lower cost and achieve an improved heat dissipation effect.

### FIELD OF THE INVENTION

The present invention relates to a heat dissipation apparatus adopted for use on heat generating elements of electronic products and particularly to a closed loop heat dissipation apparatus that costs less and has an improved heat dissipation effect.

### BACKGROUND OF THE INVENTION

With the continuous advance of semiconductor manufacturing technology, the number of transistors in the electronic elements and chip sets of electronic products also increases. Electric consumption and heat generation during operation of the electronic elements have become important issues to be resolved in the electronic industry.

Among the heat generating elements in the electronic products, heat generated by the central processing unit (CPU) is most significant. Many heat dissipation techniques have been proposed in the prior art. The heat dissipation device illustrated in FIG. 1 is one of such examples. It includes a heat absorption section 10, a vapor passage 20 and a radiation fin assembly 30. The heat absorption section 10 is a closed container filled with an operation fluid and housing a metal plate 15 which is submerged in the operation fluid. The metal plate 15 has an external heating section extended outside to connect a contact pad 16. The vapor passage 20 connects and communicates with the heat absorption section 10 to channel the vapor phase operation fluid. Heat dissipation and condensation of the operation fluid is performed through the radiation fin assembly 30 mounted on the vapor passage 20. The condensed operation fluid flows to the heat absorption section 10 again.

The heat dissipation device mentioned above aims to distribute heat energy of the heat-generating element evenly to the entire body to disperse heat. While it can achieve some degree of heat dissipation, it still has drawbacks. For instance, the vapor passage 20 is fixedly mounted onto a board to couple with the heat absorption section 10. The vapor passage 20 cannot be altered or bent. It has a certain height and occupies considerable space in the computer equipment. As a result, the computer equipment becomes quite bulky. Moreover, such type of heat dissipation device has to maintain a close contact with the heat-generating element to transfer the heat energy from the heat-generating element. To maintain the close contact, the metal plate 15 has to sustain pressure. This could cause the metal plate 15 breaking away from the heat absorption section 10 after a period of time. The operation fluid could be leaking and result in short circuit and damage of the electronic elements, and seriously affect the operation of the computer equipment.

### SUMMARY OF THE INVENTION

In view of the disadvantages occurring to the conventional techniques mentioned above, the present invention aims to provide a closed loop heat dissipation apparatus adopted for use on electronic products that has a bendable tube, costs less and can improve heat dissipation.

The closed loop heat dissipation apparatus according to the invention mainly includes a heat transfer seat, a seal lid, a tube and a radiation fin assembly. The heat transfer seat has a hollow chamber to contain an operation fluid. The seal lid seals one side of the heat transfer seat and is attached to a heat-generating element of computer equipment, and has miniature flutes formed thereon. The tube is bendable and connected to and communicates with the heat transfer seat to receive the vapor phase operation fluid that has been heated. The radiation fin assembly is mounted on the tube to make the radiation area bigger and disperse the heat energy of the operation fluid flowing in the tube to the exterior. The vapor phase operation fluid is condensed in the tube to become liquid again and flows back to the heat transfer seat through the tube. Thus the operation fluid circulates between the heat transfer seat and the tube. Therefore the heat generated by the heat-generating element during operation is evenly distributed to the entire body, and heat dissipation improves. In addition, the bendable tube may be fitted into a smaller space in the computer equipment to comply with the prevailing trend of shrinking product sizes.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a schematic view of a conventional heat dissipation device.

FIG. 2A is an exploded view of the closed loop heat dissipation apparatus of the invention.

FIG. 2B is a schematic view of the parallel miniature flutes of the invention.

FIG. 2C is a schematic view of the concentric circle miniature flutes of the invention.

FIG. 2D is a schematic view of the cross miniature flutes of the invention.

FIG. 2E is a schematic view of the tube of the invention.

FIG. 2F is a schematic view of the heat transfer seat of the invention.

FIG. 3A is a perspective view of the closed loop heat dissipation apparatus of the invention.

FIG. 3B is a schematic view of the tube of the invention in a bending condition.

FIG. 4 is a sectional view of the invention in a horizontal fashion.

FIG. 5 is a sectional view of the invention in an upright fashion.

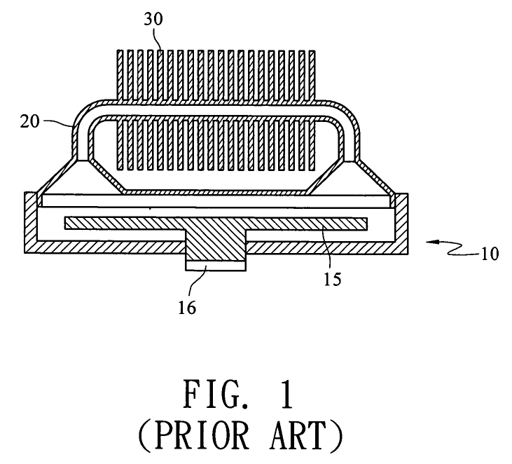

### DESCRIPTION OF THE PREFERRED EMBODIMENTS

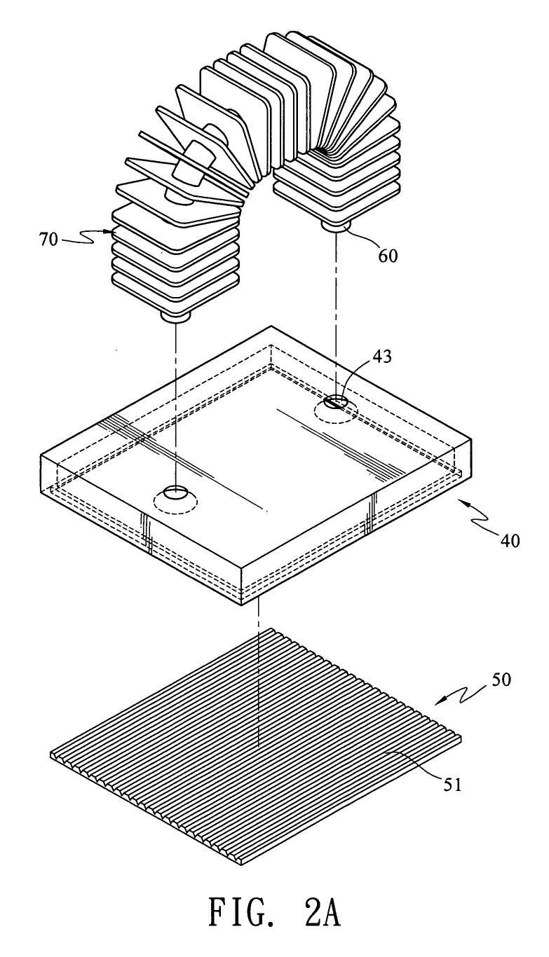

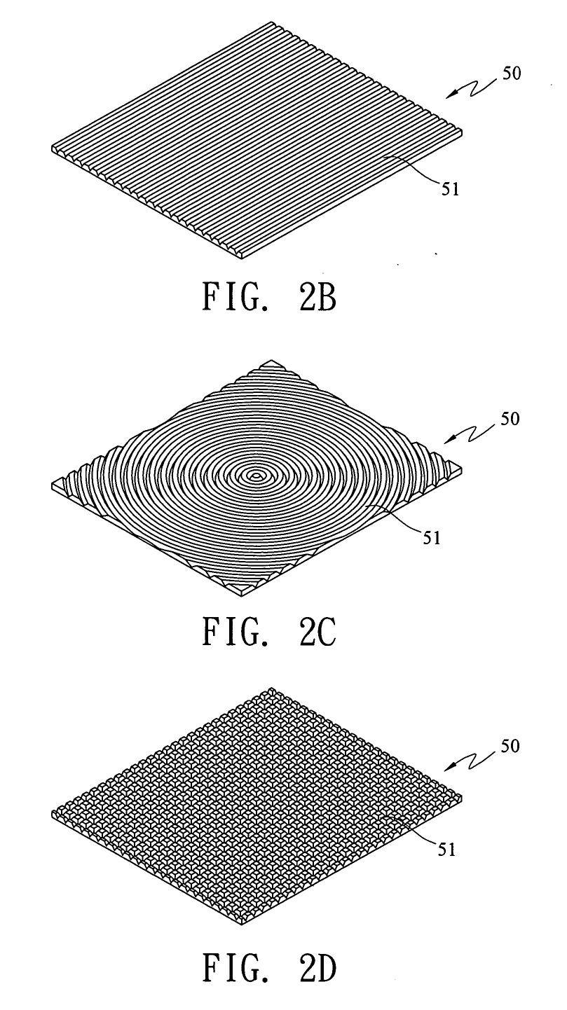

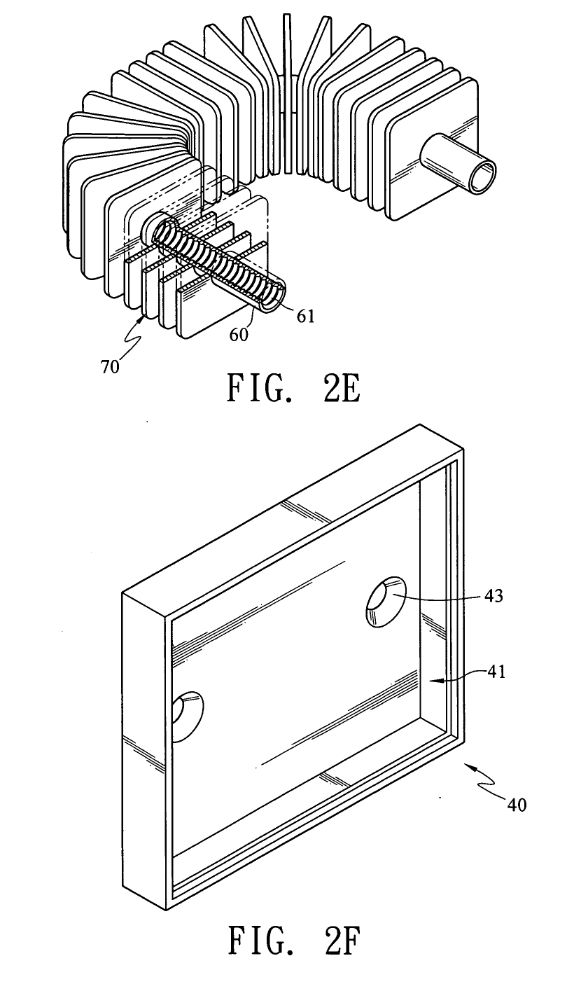

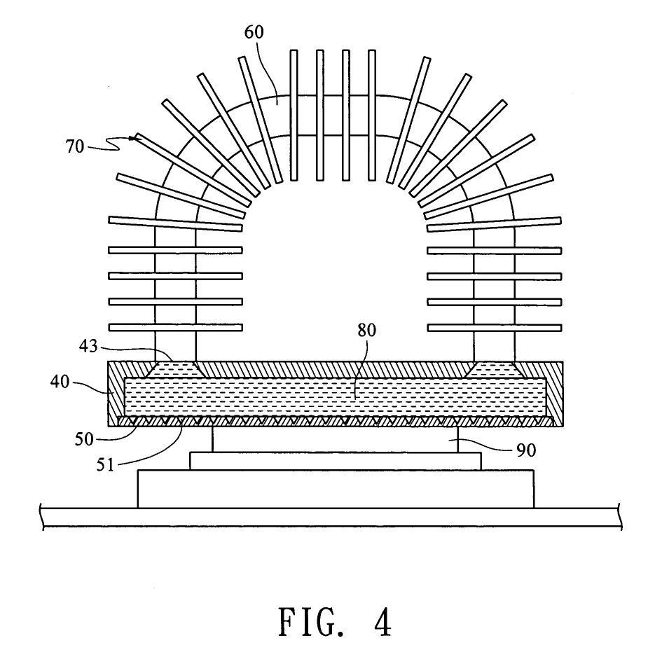

The heat dissipation apparatus according to the invention is adopted for use on electronic products. Referring to FIG. 2A, the heat dissipation apparatus includes a heat transfer seat 40, a seal lid 50, a tube 60 and a radiation fin assembly 70. The heat transfer seat 40 has a hollow chamber 41 to contain operation fluid 80. The heat transfer seat 40 is made of thermal conductive metal such as aluminum, copper or the like. The operation fluid 80 has many selections such as water, acetone, refrigerant and the like. The seal lid 50 seals one side of the heat transfer seat 40 and is attached to a heat generating element 90 (referring to FIG. 4), to keep the operation fluid 80 in the hollow chamber 41. The seal lid 50 has a plurality of miniature flutes 51 formed on one side facing the hollow chamber 41. The miniature flutes 51 have a V-shape cross section at an angle of about 60 degrees to increase the contact area of the operation fluid 80 and the seal lid 50 to allow the heat energy of the heat generating element 90 to be evenly distributed and transferred to the operation fluid 80. The miniature flutes 51 may be fabricated in many ways, such as die casting, power metallurgy, or chemical etching.

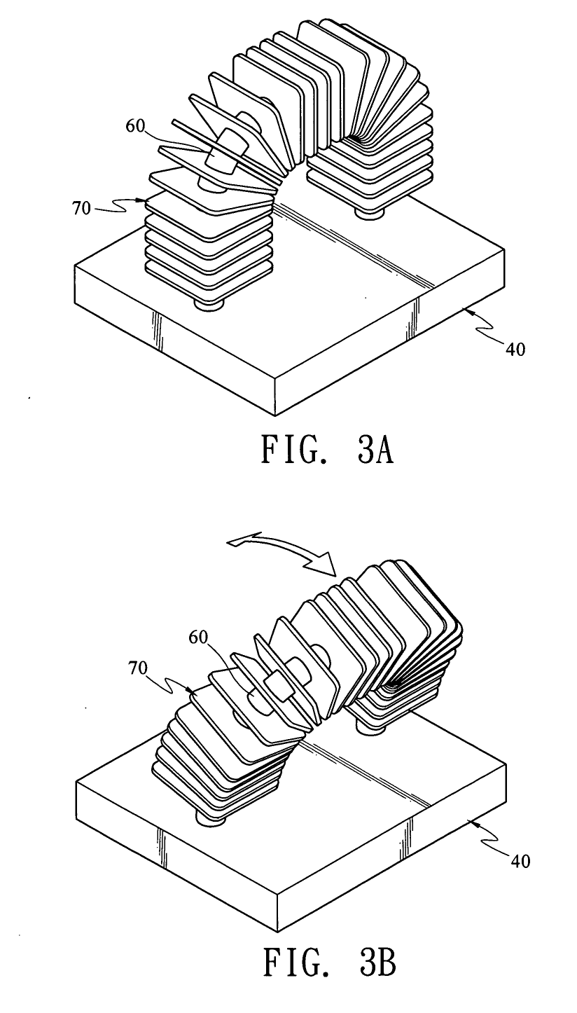

Referring to FIGS. 2E and 2F, the tube 60 has a continuous helical groove 61 formed on the inner wall. It may be made of a flexible metal and is mounted onto the topside of the heat transfer seat 40 in a bendable manner (referring to FIG. 3). If the inner installation space of the electronic product (not shown in the drawings) is limited, the tube 60 may be bent and turned relative to the heat transfer seat 40, to fit into the smaller electronic product. The heat transfer seat 40 has an umbrella-like port 43 to couple with the tube 60 and channel the tube 60 to the hollow chamber 41. The port 43 is tapered toward the topside of the heat transfer seat 40.

The miniature flutes 51 may be formed on the seal lid 50 in many styles. FIG. 2B illustrates one style in a parallel fashion. FIG. 2C shows another style in concentric circles expanding outwards. And FIG. 2D shows yet another style in a cross fashion.

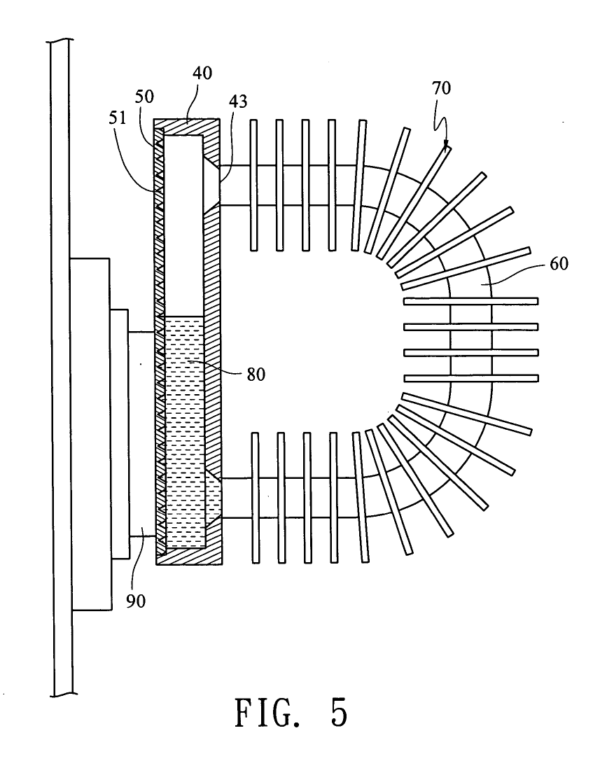

The heat dissipation apparatus according to the invention is mounted onto the heat-generating element 90 of an electronic product to transfer and disperse the heat generated during operation. Referring to FIG. 4, the seal lid 50 has one side attaching to the heat-generating element (not shown in the drawing). In order to make a close contact, the contact side of the seal lid 50 and the heat generating element 90 are coated with a heat dissipation paste to increase the heat transfer. The heat generated by the heat-generating element 90 is transferred through the seal lid 50 to the operation fluid 80 filled in the heat transfer seat. A portion of the operation fluid 80 receives the heat to become a vapor and liquid mixture or become vaporized, depending on the type of operation fluid 80 and the heat generated by the heat generating element. Namely, the operation fluid 80 might be vaporized if sufficient heat is absorbed. The vaporized operation fluid 80 enters the tube 60 from the hollow chamber 41. The radiation fin assembly 70 around the tube 60 increases the heat dissipation area to aid heat transfer to the exterior. The helical groove 61 in the tube 60 helps to gather and channel the condensed operation fluid 80 back to the hollow chamber 41. Thus the operation fluid 80 circulates between the hollow chamber 41 and the tube 60. Thereby the heat generated by the heat-generating element 90 is evenly distributed to the entire body to achieve a desired heat dissipation. Referring to FIG. 5, when the electronic product is installed in an upright manner, the operation fluid 80 flows to the lower portion of the heat transfer seat 40 and the tube 60, due to gravity, while the vaporized operation fluid 80 flows in the upper portion of the heat transfer seat 40 and the tube 60. The condensed operation fluid 80 flows to the lower portion of the heat transfer seat 40 and the tube 60 again.

Compared with a conventional heat dissipation device that requires more assembly processes and has elements that tend to break away, the present invention provides a bendable tube 60 that is adjustable angularly according to the installation space and adaptable to various types of electronic products. The height of the installation space may be reduced to meet the present trend of shrinking product sizes. The miniature flutes 51 on the seal lid 50 and the helical groove 61 in the tube 60 also can facilitate flowing of the operation fluid 80 to achieve improved heat dissipation.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments, which do not depart from the spirit and scope of the invention.

What is claimed is:

1. A closed loop heat dissipation apparatus for dispersing heat of a heat generating element through an operation fluid, comprising:
a heat transfer seat having a hollow chamber for containing the operation fluid;
a seal lid sealed one side of the heat transfer seat and attached to the heat generating element to hold the operation fluid in the heat transfer seat having a plurality of miniature flutes on one side facing the hollow chamber to increase the contact area of the operation fluid and the seal lid to evenly transfer the heat of the heat generating element to the operation fluid;
a tube made from a flexible metal mounting on the heat transfer seat in a bendable manner and communicating with the hollow chamber to channel the heated and vaporized operation fluid, and gather and channel condensed operation fluid into the hollow chamber; and
a radiation fin assembly mounted on and covered the tube to increase heat dissipation area of the tube.

2. The closed loop heat dissipation apparatus of claim 1, wherein the heat transfer seat is made of thermal conductive material.

3. The closed loop heat dissipation apparatus of claim 2, wherein the thermal conductive material is aluminum.

4. The closed loop heat dissipation apparatus of claim 1, wherein the operation fluid is selected from the group consisting of water, acetone and refrigerant.

5. The closed loop heat dissipation apparatus of claim 1, wherein the miniature flutes are fabricated by methods comprising die casting, power metallurgy and chemical etching.

6. The closed loop heat dissipation apparatus of claim 1, wherein the heat transfer seat has a umbrella-like port to couple with the tube.

7. The closed loop heat dissipation apparatus of claim 1, wherein the tube has a continuous helical groove formed on the inner wall thereof.

8. The closed loop heat dissipation apparatus of claim 1, wherein the miniature flutes have a V-shape cross section.

9. The closed loop heat dissipation apparatus of claim 8, wherein the V-shape cross section of the miniature flutes has an angle about 60 degrees.

10. The closed loop heat dissipation apparatus of claim 1, wherein the miniature flutes are formed on the seal lid in a parallel fashion.

11. The closed loop heat dissipation apparatus of claim 1, wherein the miniature flutes are formed on the seal lid in concentric circles expanding outwards.

12. The closed loop heat dissipation apparatus of claim 1, wherein the miniature flutes are formed on the seal lid in a cross fashion.

13. The closed loop heat dissipation apparatus of claim 1, wherein the attached side between the seal lid and the heat generating element is coated with a heat dissipation paste.
